(19) United States
(12) Patent Application Publication
(10) Pub. No.: US 2015/0075845 A1
(43) Pub. Date: Mar. 19, 2015

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventor: Ki Young Yoo, Suwon-Si (KR)

(73) Assignee: SAMSUNG ELECTRO-MECHANICS CO., LTD., Suwon-Si (KR)

(21) Appl. No.: 14/485,534

(22) Filed: Sep. 12, 2014

(30) Foreign Application Priority Data
Sep. 16, 2013 (KR) 10-2013-0111110

(51) Int. Cl. H05K 3/46; G03F 7/16; B23K 26/38; H05K 1/11; H05K 3/00

(52) U.S. Cl. CPC H05K 3/4644; H05K 1/115; H05K 3/4679; H05K 3/002; H05K 3/4661; H05K 3/0026; H05K 3/0023; H05K 3/0044; H05K 3/4664; B23K 26/381; G03F 7/16; H05K 2201/0137
USPC 174/251; 427/97.3; 216/13; 427/555; 427/96.9; 219/121.71; 430/315

(57) ABSTRACT

Disclosed herein are a printed circuit board and a method of manufacturing the same. According to a preferred embodiment of the present invention, the printed circuit board includes: a base substrate; an inner layer build-up layer formed on the base substrate and including a first inner layer circuit layer, a second inner layer circuit layer, an inner layer insulating layer, and an inner layer via having a tapered section; and an outer layer build-up layer formed on the inner layer build-up layer and including an outer layer circuit layer, an outer layer insulating layer, and an outer layer via having a rectangular section.

### CROSS REFERENCE TO RELATED APPLICATION

This application claims the benefit of Korean Patent Application No. 10-2013-0111110, filed on Sep. 16, 2013, entitled “Printed Circuit Board And Method Of Manufacturing The Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

With the recent development of electronic industries, a demand for multi-functional and slim and small electronic components has rapidly increased. Therefore, there is a need to increase a wiring density of a printed circuit board on which the electronic components are mounted and reduce a thickness thereof. In recent, as a demand for slim and small electronic products is inclined to be rapidly increased, a production of the printed circuit board is increased by using a build-up method of implementing a bonding between minimum circuit layers by connecting only the required circuit layers to each other, not a method of processing a plated through hole implemented in a multi-layer printed circuit board. An example of vias formed on the printed circuit board adopting the build-up method may include a staggered type via, an O-ring type via, a stack type via, and the like. Among those, the stack type via forming a via on a via may be formed in an order of forming a lower via, a circuit pattern, an upper insulating layer, and an upper via on a lower insulating layer. Further, a via hole for forming the stack type via is machined by a laser drill (U.S. Pat. No. 7,485,411).

### SUMMARY OF THE INVENTION

The present invention has been made in an effort to provide a printed circuit board capable of preventing an occurrence of dimple and a method of manufacturing the same.

Further, the present invention has been made in an effort to provide a printed circuit board capable of reducing a handling problem and a method of manufacturing the same.

According to a preferred embodiment of the present invention, there is provided a printed circuit board, including: a base substrate; an inner layer build-up layer formed on the base substrate and including a first inner layer circuit layer, a second inner layer circuit layer, an inner layer insulating layer, and an inner layer via having a tapered section; and an outer layer build-up layer formed on the inner layer build-up layer and including an outer-layer circuit layer, an outer layer insulating layer, and an outer layer via having a rectangular section.

The inner layer build-up layer may include at least one of the first inner layer circuit layer, the second inner layer circuit layer, the inner layer insulating layer, and the inner layer via.

The inner layer build-up layer may include: the first inner layer circuit layer formed on the base substrate; the inner layer insulating layer formed on the base substrate and the first inner layer circuit layer; the inner layer via formed on the first inner layer circuit layer and formed to penetrate through the inner layer insulating layer; and the second inner layer circuit layer formed on the inner layer insulating layer and the inner layer via.

The outer layer build-up layer may include: the outer layer insulating layer formed on the inner layer build-up layer; the outer layer via formed on the inner layer build-up layer and formed to penetrate through the outer layer insulating layer; and the outer layer circuit layer formed on the outer layer insulating layer and the outer layer via.

The outer layer insulating layer may be made of a photosensitive insulating material.

The inner layer build-up layer and the outer layer build-up layer may be formed on both surfaces of the base substrate.

According to another preferred embodiment of the present invention, there is provided a method of manufacturing a printed circuit board including: preparing a base substrate; forming an inner layer build-up layer including a first inner layer circuit layer, a second inner layer circuit layer, an inner layer insulating layer, and an inner layer via having a tapered section on the base substrate; and forming an outer layer build-up layer including an outer layer circuit layer, an outer layer insulating layer, and an outer layer via having a rectangular section on the inner layer build-up layer.

The inner layer build-up layer may include at least one of the first inner layer circuit layer, the second inner layer circuit layer, the inner layer insulating layer, and the inner layer via.

The forming of the inner layer build-up layer may include: forming the first inner layer circuit layer on the base substrate; forming the inner layer insulating layer on the first inner layer circuit layer; and forming the inner layer via and the second inner layer circuit layer on the inner layer insulating layer.

The forming of the inner layer via and the second inner layer circuit layer may include: forming an inner layer via hole having a tapered section in the inner layer insulating layer by using a laser drill; forming an inner layer conductive layer and the inner layer via by forming a conductive material in the inner layer insulating layer and the inner layer via hole; forming a first etching resist passivating a region, in which the second inner layer circuit layer is formed, on the inner layer conductive layer; forming the second inner layer circuit layer by etching the inner layer conductive layer exposed by the first etching resist; and removing the first etching resist.

The forming of the inner layer via and the second inner layer circuit layer may include: forming the inner layer via hole having the tapered section in the inner layer insulating layer by using the laser drill; forming a first plating resist exposing a region, in which the inner layer via hole and the second inner layer circuit layer are formed, on the inner layer insulating layer; forming the inner layer via and the second inner layer circuit layer by forming the inner layer via hole and the inner layer insulating layer exposed by the first plating resist; and removing the first plating resist.

The forming of the outer layer build-up layer may include: forming the outer layer via on the inner layer build-up layer; forming the outer layer insulating layer formed on the inner layer build-up layer and having the outer layer via embedded therein; and forming the outer layer circuit layer on the outer layer insulating layer and the outer layer via.

The forming of the outer layer via may include: forming a photosensitive resist on the inner layer build-up layer; forming an opening having a rectangular section and exposing a region in which the outer layer via is formed, by exposing and developing the photosensitive resist; forming the outer layer via by forming an insulating material in the opening; polishing and planarizing an upper portion of the outer layer via; and removing the photosensitive resist.

The method of manufacturing a printed circuit board may further include: after the forming of the outer layer insulating layer, polishing and planarizing the outer layer insulating layer and the outer layer via.

The forming of the outer layer circuit layer may include: forming an outer layer conductive layer by forming an insulating material in the outer layer insulating layer and the outer layer via; forming a second etching resist on the outer layer conductive layer to passivate a region in which the outer layer circuit layer is formed; forming the outer layer circuit layer by etching the outer layer conductive layer exposed by the second etching resist; and removing the second etching resist.

The forming of the outer layer circuit layer may include: forming a second plating resist which exposes the outer layer insulating layer and the region in which the outer layer circuit layer is formed in the outer layer via; forming the outer layer circuit layer by forming a conductive material in the outer layer insulating layer and the outer layer via exposed by the second plating resist; and removing the second plating resist.

The forming of the outer layer build-up layer may include: forming the outer layer insulating layer made of a photosensitive insulating material on the inner layer build-up layer; forming the outer layer via formed to penetrate through the outer layer insulating layer; and forming the outer layer circuit layer on the outer layer insulating layer and the outer layer via.

The forming of the outer layer via may include: forming an outer layer via hole having a rectangular section and exposing a region in which the outer layer via is formed, by exposing and developing the outer layer insulating layer; forming the outer layer via by forming the conductive material in the outer layer via hole; and polishing and planarizing upper portions of the outer layer insulating layer and the outer layer via.

The forming of the outer layer circuit layer may include: forming the outer layer conductive layer by forming an insulating material in the outer layer insulating layer and the outer layer via; forming a second etching resist on the outer layer conductive layer to passivate the region in which the outer layer circuit layer is formed; forming the outer layer circuit layer by etching the outer layer conductive layer exposed by the second etching resist; and removing the second etching resist.

The forming of the outer layer circuit layer may include: forming a second plating resist which exposes the outer layer insulating layer and the region in which the outer layer circuit layer is formed in the outer layer via; forming the outer layer circuit layer by forming the conductive material in the outer layer insulating layer and the outer layer via exposed by the second plating resist; and removing the second plating resist.

The inner layer build-up layer and the outer layer build-up layer may be formed on both surfaces of the base substrate.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating a printed circuit board according to a preferred embodiment of the present invention;

FIGS. 2 to 24 are exemplified diagrams illustrating a method of manufacturing a printed circuit board according to the preferred embodiment of the present invention;

FIG. 25 is an exemplified diagram illustrating a printed circuit board according to another preferred embodiment of the present invention; and

FIGS. 26 to 30 are exemplified diagrams illustrating a method of manufacturing a printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

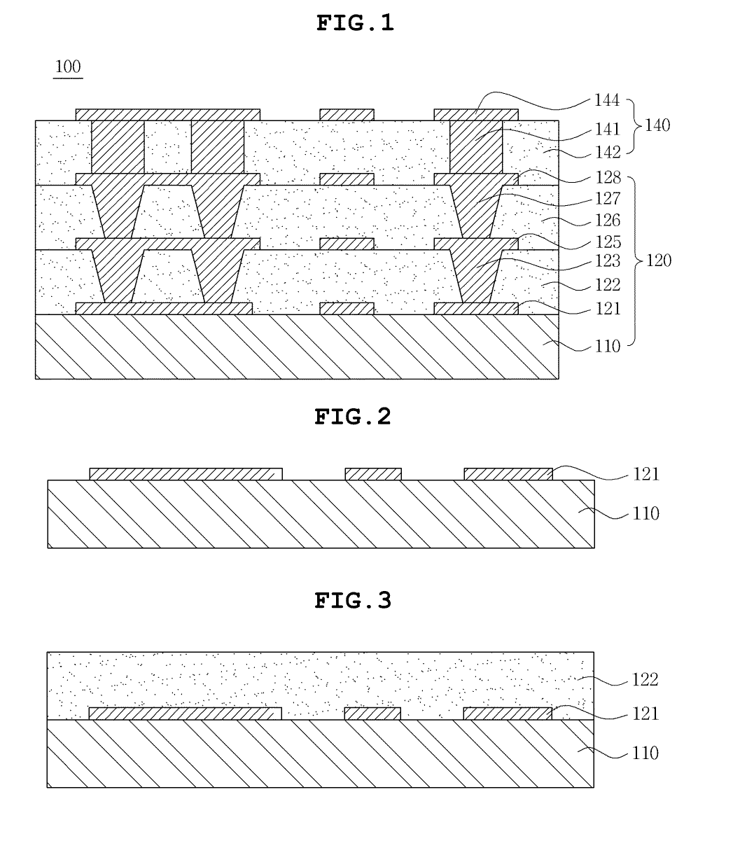

FIG. 1 is an exemplified diagram illustrating a printed circuit board according to a preferred embodiment of the present invention.

Referring to FIG. 1, a printed circuit board 100 may include a base substrate 110, an inner layer build-up layer 120, and an outer layer build-up layer 140.

The base substrate 110 may be generally made of a composite polymer resin used as an interlayer insulating material. For example, the base substrate 110 adopts a prepreg, and thus the printed circuit board may be manufactured to be thinner. Alternatively, the base substrate 110 may adopt an ajinomoto build up film (ABF) to easily implement a fine circuit. In addition, the base substrate 110 may use an epoxy based resin, such as FR-4 and bismaleimide triazine (BT), but the preferred embodiment of the present invention is not particularly limited thereto. Further, the base substrate 110 may be formed using a copper clad laminate (CCL). The preferred embodiment of the present invention illustrates that the base substrate 110 is formed of a single insulating layer, but is not limited thereto. That is, the base substrate 110 may be a build-up layer which is configured to include at least one layer of insulating layer and circuit layer, and a via.

The inner layer build-up layer 120 is formed on the base substrate 110. According to the preferred embodiment of the present invention, the inner layer build-up layer 120 includes a first inner layer circuit layer 121, a first inner layer insulating layer 122, a first inner layer via 123, a second inner layer circuit layer 125, a second inner layer insulating layer 126, a second inner layer via 127, and a third inner layer circuit layer 128.

The first inner layer circuit layer 121 is formed on the base substrate 110.

The first inner layer insulating layer 122 is formed on the base substrate 110 and the first inner layer circuit layer 121.

The first inner layer via 123 is formed in the first inner layer insulating layer 122. The first inner layer via 123 may electrically connect the first inner layer circuit layer 121 to the second inner layer circuit layer 125 by penetrating through the first inner layer insulating layer 122. That is, one surface of the first inner layer via 123 may be bonded to the second inner layer circuit layer 125 and the other surface thereof may be bonded to the first inner layer circuit layer 121. According to the preferred embodiment of the present invention, a section of the first inner layer via 123 has a taper shape. That is, one surface of the first inner layer via 123 may be formed to have a diameter larger than that of the other surface thereof. According to the preferred embodiment of the present invention, in order to form the first inner layer via 123, a first inner layer via hole (not illustrated) is formed using a laser drill. In this case, in characteristics of the laser drill, the first inner layer via hole (not illustrated) is formed to have a tapered section. Therefore, the first inner layer via 123 formed by filling the first inner layer via hole (not illustrated) with a conductive material is also formed to have the tapered section.

The second inner layer circuit layer 125 is formed on the first inner layer insulating layer 122 and the first inner layer via 123. The second inner layer circuit layer 125 is bonded to one surface of the first inner layer via 123.

The second inner layer insulating layer 126 is formed on the first inner layer insulating layer 122 and the first inner layer via 123.

The second inner layer via 127 is formed in the second inner layer insulating layer 126. The second inner layer via 127 may electrically connect the second inner layer circuit layer 125 to the third inner layer circuit layer 128 by penetrating through the second inner layer insulating layer 126. That is, one surface of the second inner layer via 127 may be bonded to the third inner layer circuit layer 128 and the other surface thereof may be bonded to the second inner layer circuit layer 125. According to the preferred embodiment of the present invention, in order to form the second inner layer via 127, a second inner layer via hole (not illustrated) is formed using the laser drill. Therefore, similar to the first inner layer via 123, the second inner layer via 127 may also have the tapered section. That is, one surface of the second inner layer via 127 may be formed to have a diameter larger than that of the other surface thereof.

The third inner layer circuit layer 128 is formed on the second inner layer insulating layer 126 and the second inner layer via 127.

The preferred embodiment of the present invention describes that the inner layer build-up layer 120 includes two layers of insulating layer and three layers of circuit layer, but is not limited thereto. That is, the inner layer build-up layer 120 may be configured of the insulating layer and the circuit layer of various number of layers by a selection of those skilled in the art.

The outer layer build-up layer 140 is formed on the inner layer build-up layer 120 as the uppermost layer among the build-up layers of the printed circuit board 100. According to the preferred embodiment of the present invention, the outer layer build-up layer 140 includes an outer layer insulating layer 142, an outer layer via 141, and an outer layer circuit layer 144.

The outer layer insulating layer 142 is formed on the second inner layer insulating layer 126 and the third inner layer circuit layer 128.

The outer layer via 141 is formed in the outer layer insulating layer 142. The outer layer via 141 may electrically connect the third inner layer circuit layer 128 to the outer layer circuit layer 144 by penetrating through the outer layer insulating layer 142. That is, one surface of the outer layer via 141 may be bonded to the outer layer circuit layer 144 and the other surface thereof may be bonded to the third inner layer circuit layer 128. According to the preferred embodiment of the present invention, a section of the outer layer via 141 has a rectangular shape. That is, one surface and the other surface of the outer layer via 141 may be formed to have the same diameter. According to the preferred embodiment of the present invention, in order to form the outer layer via 141, an opening provided with the outer layer via 141 is formed by performing exposure and developing on a photosensitive resist (not illustrated). In this case, the opening formed on the photosensitive resist (not illustrated) is formed to have the rectangular section. Therefore, the opening of the photosensitive resist (not illustrated) is filled with the conductive material and the outer layer via 141 formed by polishing an upper portion of the opening is formed to have the rectangular section.

The outer layer circuit layer 144 is formed on the outer layer insulating layer 142 and the outer layer via 141. The outer layer circuit layer 144 is bonded to one surface of the outer layer via 141.

According to the preferred embodiment of the present invention, the first inner layer circuit layer 121, the first inner layer via 123, the second inner layer circuit layer 125, the second inner layer via 127, the third inner layer circuit layer 128, the outer layer via 141, and the outer layer circuit layer 144 may be made of the conductive material. For example, the conductive material may be copper. However, the conductive material is not limited to the copper, but any conductive material for the circuit used in the circuit board field may be used.

The first inner layer insulating layer 122, the second inner layer insulating layer 126, and the outer layer insulating layer 142 are generally made of the composite polymer resin which is used as the interlayer insulating material. For example, the first inner layer insulating layer 122, the second inner layer insulating layer 126, and the outer layer insulating layer 142 may be made of an epoxy-based resin, such as a prepreg, an ajinomoto build up film (ABF), FR-4, and bismaleimide triazine (BT).

In the printed circuit board according to the preferred embodiment of the present invention, the inner layer via has the tapered section by the laser drill machining and the outer layer via has the rectangular section by the exposure and developing processes. An advantage of the printed circuit board having the foregoing structure will be described in a method of manufacturing the same.

FIGS. 2 to 24 are exemplified diagrams illustrating a method of manufacturing a printed circuit board according to the preferred embodiment of the present invention.

First, FIGS. 2 to 12 illustrate a sequence of forming the inner layer build-up layer on the base substrate.

Referring to FIG. 2, the base substrate 110 is provided.

The base substrate 110 may be generally made of the composite polymer resin used as an interlayer insulating material. For example, the base substrate 110 adopts a prepreg, and thus the printed circuit board may be manufactured to be thinner. Alternatively, the base substrate 110 may adopt an ajinomoto build up film (ABF) to easily implement a fine circuit. In addition, the base substrate 110 may use an epoxy based resin, such as FR-4 and bismaleimide triazine (BT), but the preferred embodiment of the present invention is not particularly limited thereto. Further, the base substrate 110 may be formed using the copper clad laminate (CCL). The preferred embodiment of the present invention illustrates that the base substrate 110 is formed of a single insulating layer, but is not limited thereto. That is, the base substrate 110 may be a build-up layer which is configured to include at least one layer of insulating layer and circuit layer, and a via.

The base substrate 110 may be provided with the first inner layer circuit layer 121. The first inner layer circuit layer 121 may be made of a conductive material. For example, the first inner layer circuit layer 121 may be made of copper. However, a material forming the first inner layer circuit layer 121 is not limited to the copper, but any conductive material for the circuit in the circuit board field may be applied without being limited. According to the preferred embodiment of the present invention, the first inner layer circuit layer 121 may include a circuit pattern and a pad which is electrically connected to the via.

Referring to FIG. 3, the base substrate 110 and the first inner layer circuit layer 121 are provided with the first inner layer insulating layer 122.

The first inner layer insulating layer 122 may be generally made of the composite polymer resin generally used as the interlayer insulating material. For example, the first inner layer insulating layer 122 may be made of the epoxy based resin, such as a prepreg, an ajinomoto build up film (ABF), FR-4, and bismaleimide triazine (BT).

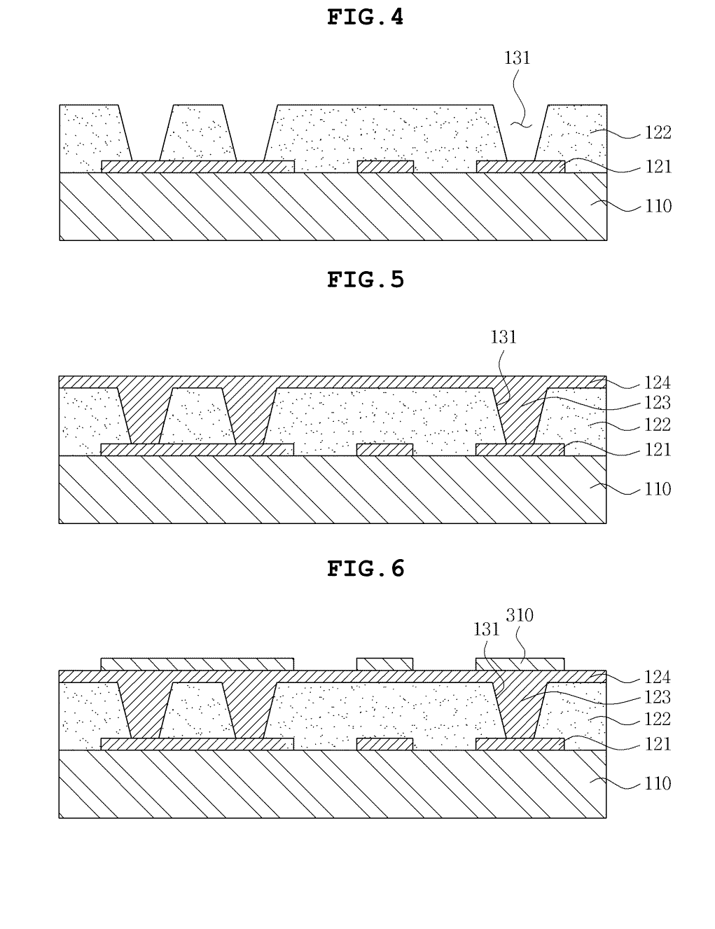

Referring to FIG. 4, the first inner layer insulating layer 122 is provided with the first inner layer via hole 131.

The first inner layer via hole 131 may be formed by machining the first inner layer insulating layer 122 with the laser drill. The first inner layer via hole 131 is machined by the laser drill and thus may be formed to have the tapered section. That is, an upper portion of the first inner layer via hole 131 may be formed to have a diameter larger than that of a lower portion thereof. The first inner layer via hole 131 may be formed on the first inner layer circuit layer 121.

FIGS. 5 to 7 are exemplified diagrams illustrating a method of forming a second inner layer circuit layer according to the preferred embodiment of the present invention.

Referring to FIG. 5, the first inner layer via 123 and a first inner layer conductive layer 124 are formed.

The first inner layer via 123 and the first inner layer conductive layer 124 may be simultaneously formed by plating the first inner layer insulating layer 122 and the first inner layer via hole 131. Herein, the first inner layer via 123 and the first inner layer conductive layer 124 may be made of the conductive material for the circuit, such as copper. The first inner layer via 123 and the first inner layer conductive layer 124 may be formed by one of the plating, a screen printing method, and an inkjet method, and the like which may be applied to the circuit board field.

According to the preferred embodiment of the present invention, the first inner layer conductive layer 124 may be formed on the first inner layer insulating layer 122 and the first inner layer via 123 may be formed in the first inner layer via hole 131.

Referring to FIG. 6, a first etching resist 310 is formed on the first inner layer conductive layer 124.

The first etching resist 310 may be provided with an opening through which a region to be removed by etching is exposed. That is, as illustrated in FIG. 6, the first etching resist 310 may be patterned to passivate a region in which the second inner layer circuit layer (not illustrated) is formed.

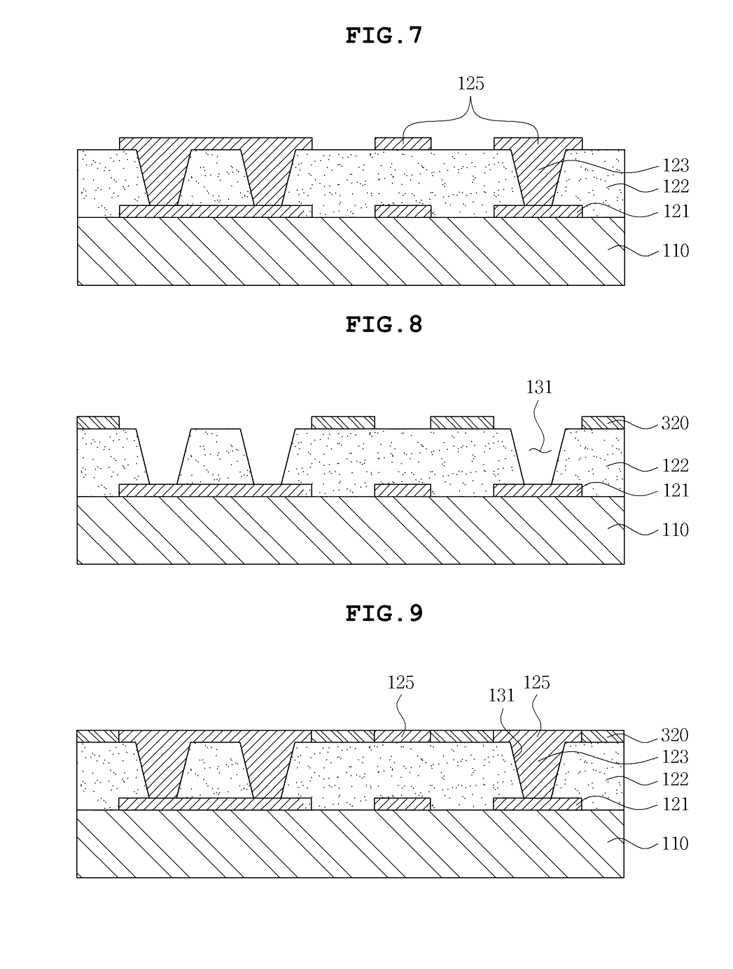

Referring to FIG. 7, the second inner layer circuit layer 125 is formed.

The second inner layer circuit layer 125 may be formed by etching the first inner layer conductive layer 124 which is exposed by the first etching resist 310 (FIG. 6). That is, in the first inner layer conductive layer 124, the region passivated by the first etching resist 310 (FIG. 6) may be the second inner layer circuit layer 125. After the etching is performed, the first etching resist 310 is removed. As described above, the second inner layer circuit layer 125 according to the preferred embodiment of the present invention may be formed by applying a tenting method.

FIGS. 8 and 9 are exemplified diagrams illustrating a method of forming a second inner layer circuit layer according to another preferred embodiment of the present invention.

Referring to FIG. 8, the first plating resist 320 is formed on the first inner layer insulating layer 122.

The first plating resist 320 may be provided with the region in which the second inner layer circuit layer 125 (FIG. 7) is formed and the opening through which the first inner layer via hole 131 is exposed.

Referring to FIG. 9, the second inner layer circuit layer 125 and the first inner layer via 123 are formed.

The second inner layer circuit layer 125 and the first inner layer via 123 may be simultaneously formed by plating the opening of the first plating resist 320. Herein, the second inner layer circuit layer 125 and the first inner layer via 123 may be made of the conductive material for the circuit, such as copper. The second inner layer circuit layer 125 and the first inner layer via 123 may be formed by one of the plating, the screen printing method, and the inkjet method, and the like which are used in the circuit board field.

Next, when the first plating resist 320 is removed, as illustrated in FIG. 7, the second inner layer circuit layer 125 and the first inner layer via 123 may be formed.

As described above, the second inner layer circuit layer 125 and the first inner layer via 123 according to another preferred embodiment of the present invention may be formed by using a semi additive process (SAP) method.

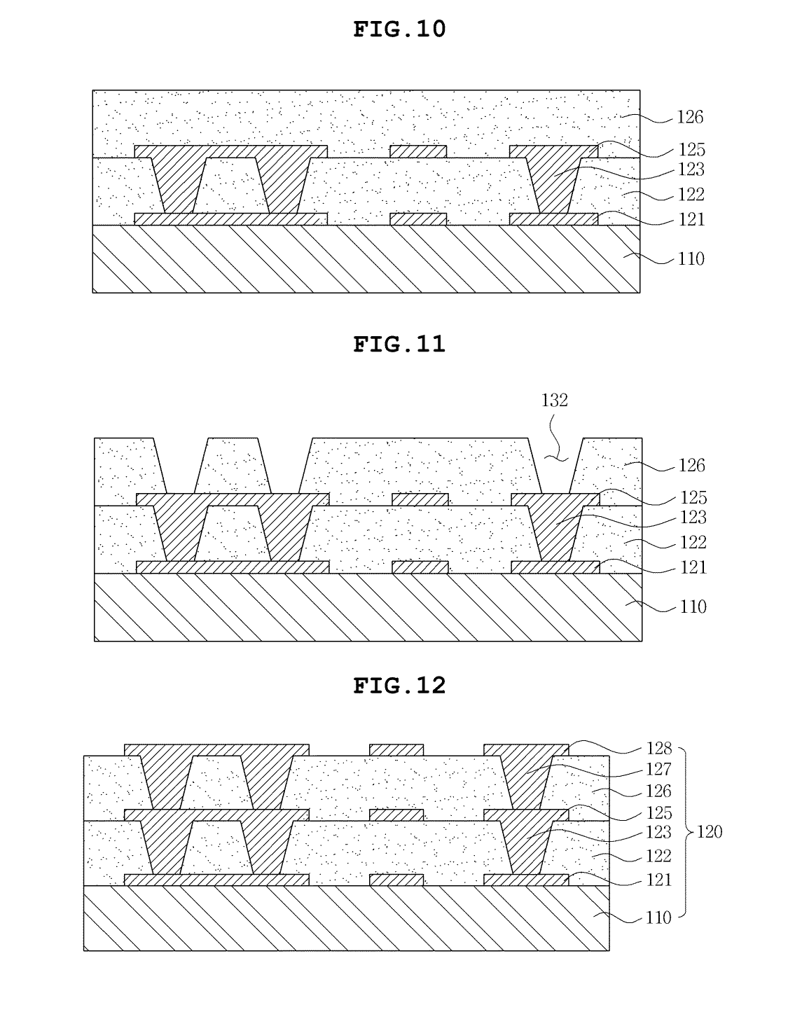

Referring to FIG. 10, the first inner layer insulating layer 122 and the second inner layer circuit layer 125 are provided with the second inner layer insulating layer 126.

The second inner layer insulating layer 126 may be generally made of the composite polymer resin generally used as the interlayer insulating material. For example, the second inner layer insulating layer 126 may be made of the epoxy based resin, such as a prepreg, an ajinomoto build up film (ABF), FR-4, and bismaleimide triazine (BT). Further, the second inner layer insulating layer 126 may have a substrate form or a film form.

Referring to FIG. 11, the second inner layer insulating layer 126 is provided with the second inner layer via hole 132.

The second inner layer via hole 132 may be formed by machining the second inner layer insulating layer 126 with the laser drill. The second inner layer via hole 132 is machined by the laser drill and thus may be formed to have the tapered section. That is, an upper portion of the second inner layer via hole 132 may be formed to have a diameter larger than that of a lower portion thereof. The second inner layer via hole 132 may be formed on the first inner layer circuit layer 121.

Referring to FIG. 12, the second inner layer insulating layer 126 and the second inner layer via hole 132 are provided with the second inner layer via 127 and the third inner layer circuit layer 128.

The second inner layer via 127 and the third inner layer circuit layer 128 may be formed by using the method of forming the first inner layer via 123 and the second inner layer circuit layer 125 as described above.

According to the method of FIGS. 2 to 12 as described above, the base substrate 110 may be provided with the inner layer build-up layer 120. The preferred embodiment of the present invention illustrates that the two layers of insulating layer and the three layers of circuit layer are formed, but the number of layers of the insulating layer and the circuit layer included in the inner layer build-up layer 120 may be freely implemented by the selection of those skilled in the art.

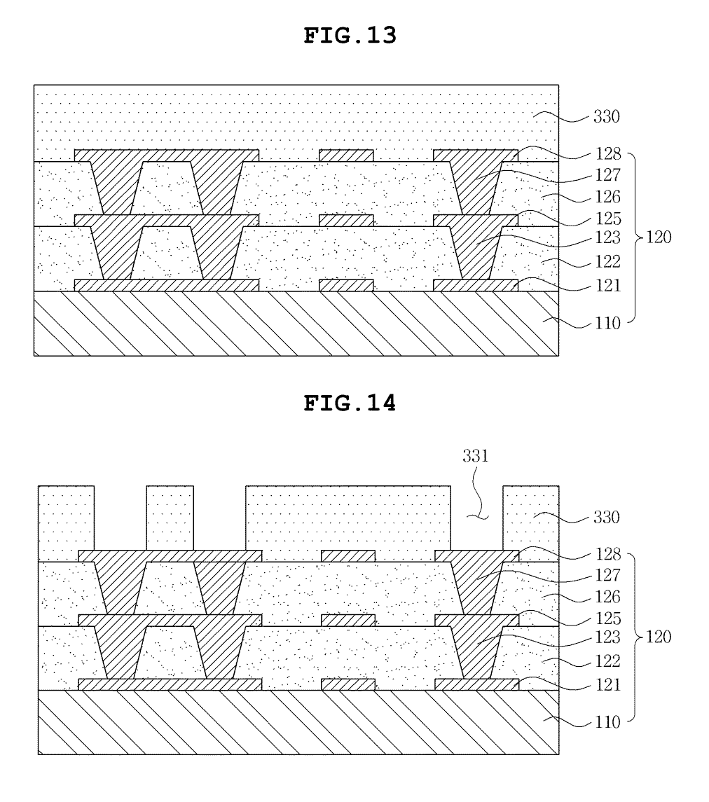

FIGS. 13 to 24 illustrate a sequence of forming the outer layer build-up layer.

Referring to FIG. 13, the second inner layer insulating layer 126 and the third inner layer circuit layer 128 are provided with a photosensitive resist 330. The positive resist 330 may be any of a positive type and a negative type. For example, the photosensitive resist 330 may be a dry film.

Referring to FIG. 14, the photosensitive resist 330 is provided with an opening 331.

The opening 331 of the photosensitive resist 330 may be formed in the region in which the outer layer via (not illustrated) is formed. The opening 331 of the photosensitive resist 330 is formed by the exposure and developing processes. Therefore, the opening 331 of the photosensitive resist 330 may be formed to have the rectangular section. That is, the opening 331 of the photosensitive resist 330 may be formed so that upper and lower portions thereof have the same diameter. The opening 331 of the photosensitive resist 330 may be formed on the third inner layer circuit layer 128.

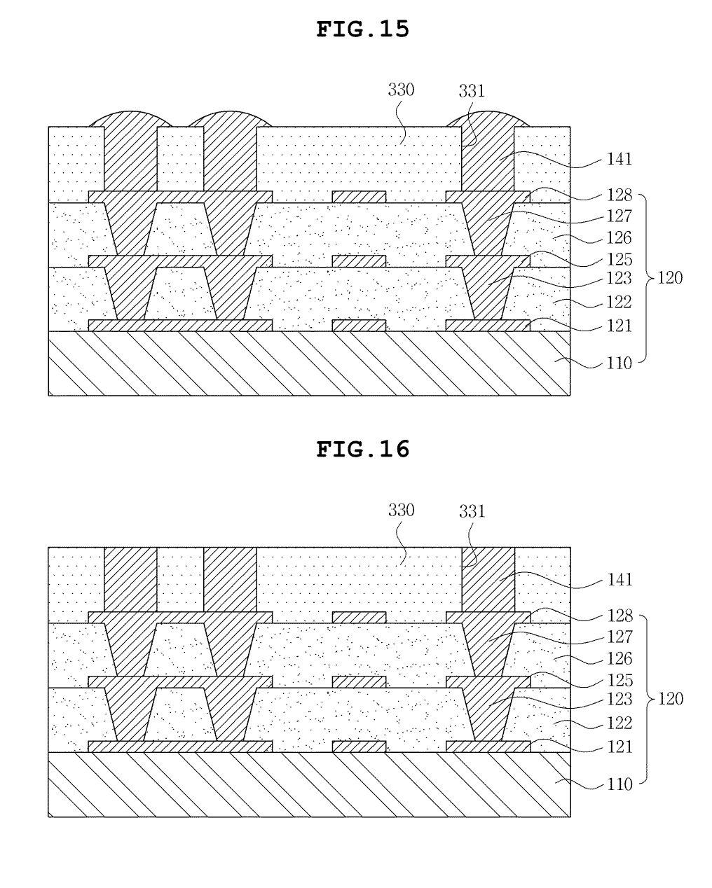

Referring to FIG. 15, the outer layer via 141 is formed.

The outer layer via 141 may be formed by plating the opening 331 of the photosensitive resist 330. Herein, the outer layer via 141 may be made of the conductive material for the circuit, such as copper. Further, the outer layer via 141 may be formed by any one of the plating, the screen printing method, the inkjet method, and the like which are used in the circuit board field. A lower surface of the outer layer via 141 may be bonded to the third inner layer circuit layer 128.

Referring to FIG. 16, an upper portion of the outer layer via 141 is polished.

The outer layer via 141 may be overcoated up to an upper portion of the photosensitive resist 330 as illustrated in FIG. 15. Further, although not illustrated, the outer layer via 141 may not be sufficiently formed up to an upper surface of the opening 331 of the photosensitive resist 330. Therefore, the upper portion of the outer layer via 141 may be planarized by being polished.

As described above, a dimple formed on the upper portion of the outer layer via 141 may be removed by polishing the upper portion of the outer layer via 141. Further, the occurrence of the dimple on the outer layer circuit layer (not illustrated) formed on the upper portion of the outer layer via 141 may be prevented by removing the dimple on the outer layer via 141.

Further, when the outer layer via 141 is formed in plural, all the outer layer vias may be formed to have a uniform height.

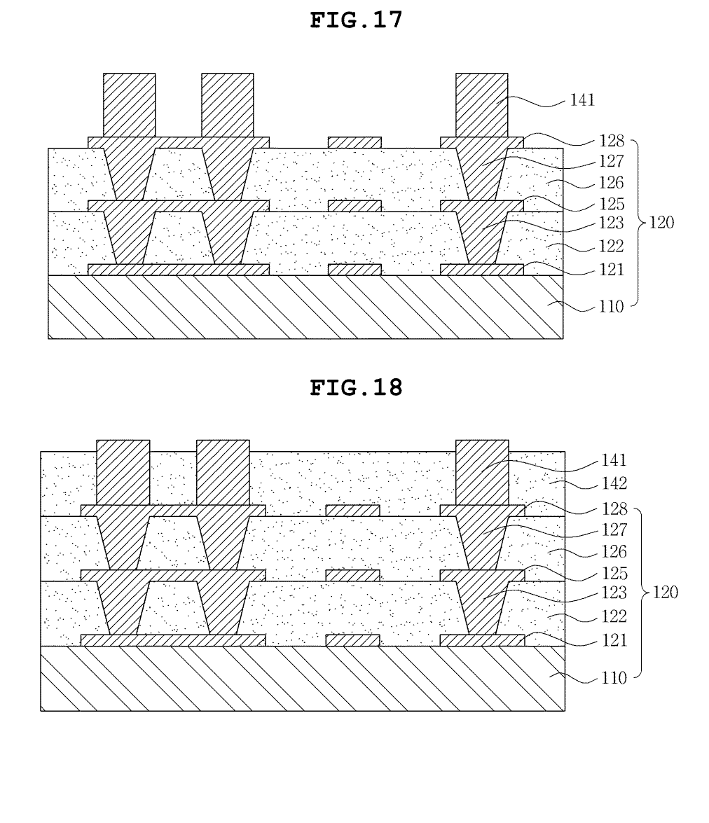

Referring to FIG. 17, the photosensitive resist 330 (FIG. 16) may be removed.

At the time of removing the photosensitive resist 330 (FIG. 16), the outer layer via 141 remains on the third inner layer circuit layer 128 in a filler form.

Referring to FIG. 18, the second inner layer insulating layer 126 and the third inner layer circuit layer 128 may be provided with the outer layer insulating layer 142. The outer layer insulating layer 142 may be generally made of the composite polymer resin used as the interlayer insulating material. For example, the outer layer insulating layer 142 may be made of an epoxy based resin, such as prepreg, ajinomoto build up film (ABF), FR-4, bismaleimide triazine (BT), and the like.

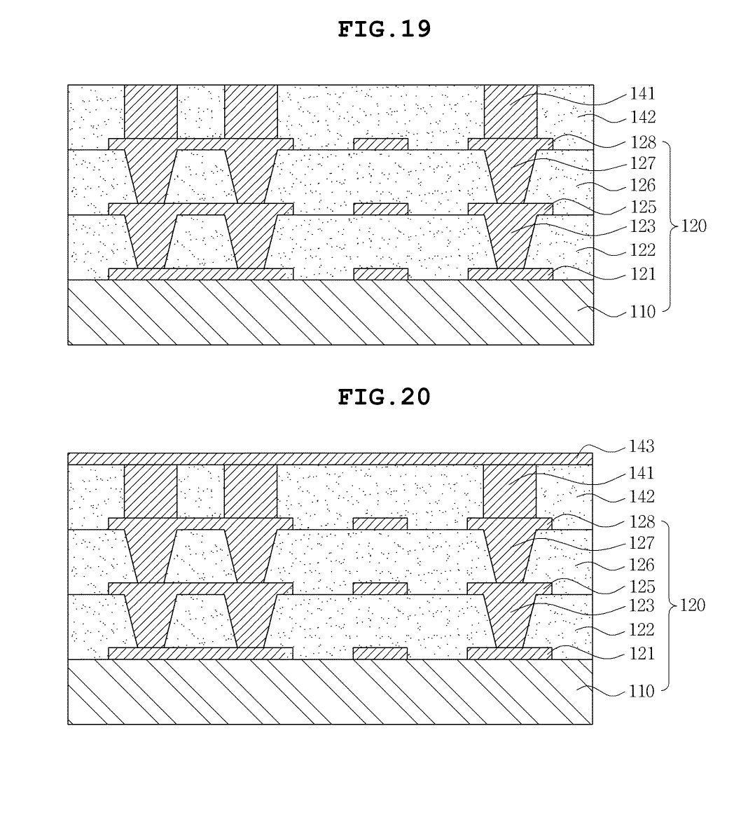

Referring to FIG. 19, upper surfaces of the outer layer insulating layer 142 and the outer layer via 141 are polished.

As illustrated in FIG. 18, the outer layer insulating layer 142 may be formed to have a thickness smaller than that of the outer layer via 141. Further, although not illustrated, the outer layer insulating layer 142 is formed to have a thickness larger than that of the outer layer via 141 to be able to enclose the upper portion of the outer layer via 141. Therefore, the outer layer insulating layer 142 and the outer layer via 141 may be planarized by being polished. By the planarization, the outer layer insulating layer 142 has the outer layer via 141 embedded therein but may be formed to expose the upper surface to the outside.

FIGS. 20 to 22 are exemplified diagrams illustrating a method of forming an outer layer circuit layer according to the preferred embodiment of the present invention.

Referring to FIG. 20, the outer layer insulating layer 142 and the outer layer via 141 are provided with an outer layer conductive layer 143.

The outer layer conductive layer 143 may be formed by plating the outer layer insulating layer 142 and the outer layer via 141. The outer layer conductive layer 143 may be made of the conductive material for the circuit, such as copper. The outer layer conductive layer 143 may be formed by any one of the plating, the screen printing method, the inkjet method, and the like which are used in the circuit board field.

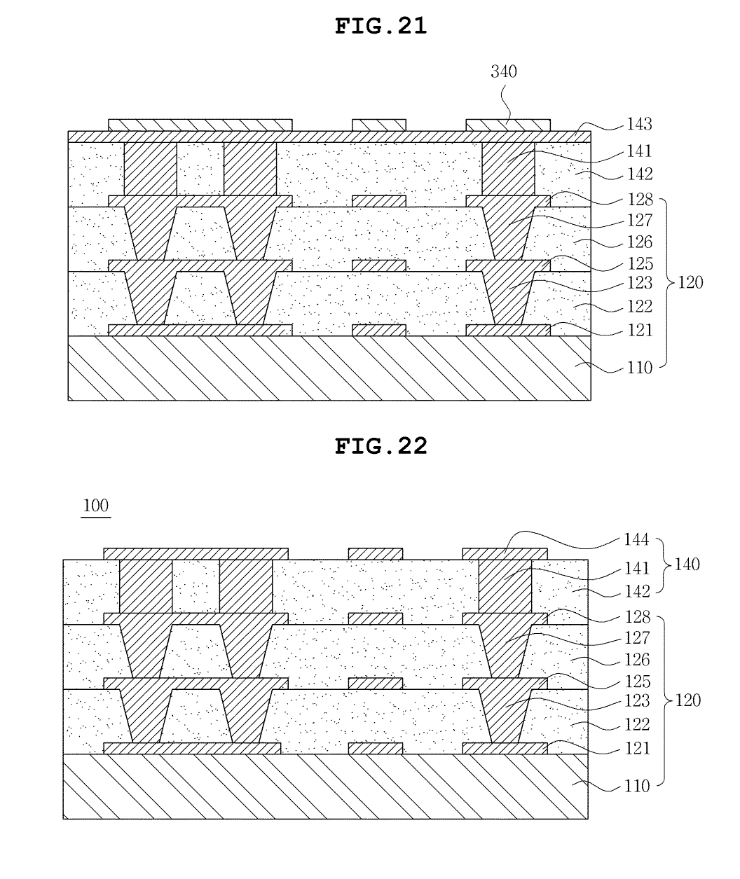

Referring to FIG. 21, the outer layer conductive layer 143 is provided with a second etching resist 340.

The second etching resist 340 may be provided with the opening through which the region to be removed by etching is exposed. That is, the second etching resist 340 may be patterned to passivate the region in which the outer layer circuit layer (not illustrated) is formed.

Referring to FIG. 22, the outer layer circuit layer 144 is formed.

The outer layer circuit layer 144 may be formed by etching the outer layer conductive layer 143 (FIG. 21) which is exposed by the second etching resist 340 (FIG. 21). That is, the outer layer conductive layer 143 passivated by the second etching resist 340 (FIG. 21) may be the outer layer circuit layer 144. After the etching is performed, the second etching resist 340 (FIG. 21) is removed.

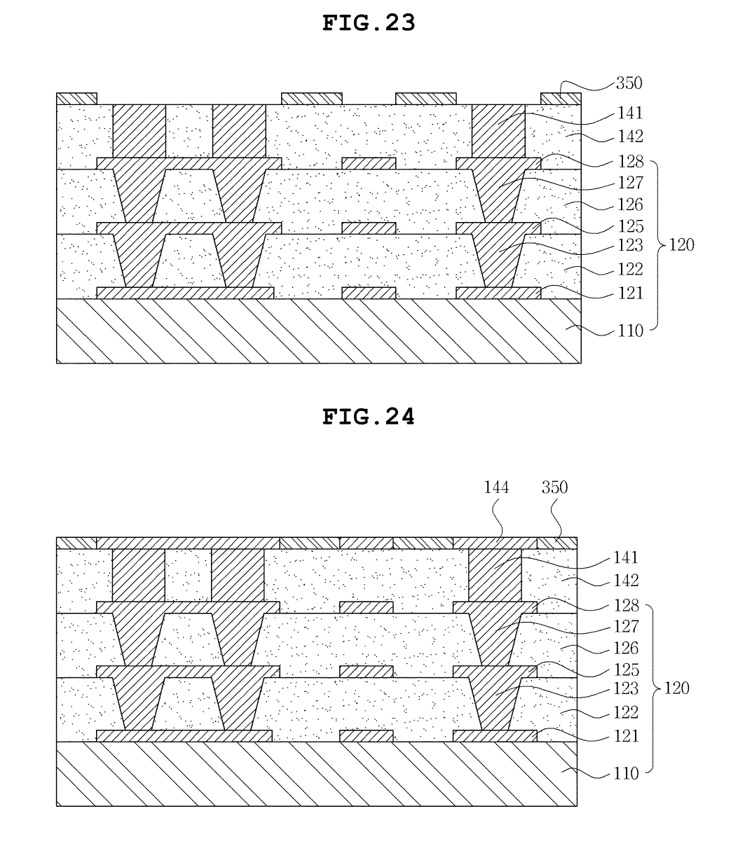

FIGS. 23 to 24 are exemplified diagrams illustrating the method of forming an outer layer circuit layer 144 according to another preferred embodiment of the present invention.

Referring to FIG. 23, the outer layer insulating layer 142 and the outer layer via 141 are provided with a second plating resist 350.

The second plating resist 350 may be provided with the opening through which the region provided with the outer layer circuit layer 144 (FIG. 22) is exposed.

Referring to FIG. 24, the outer layer circuit layer 144 is formed.

The outer layer circuit layer 144 may be formed by plating the opening of the second plating resist 350. The outer layer conductive layer 143 may be made of the conductive material for the circuit, such as copper. The outer layer conductive layer 143 may be formed by any one of the plating, the screen printing method, the inkjet method, and the like which are used in the circuit board field.

Next, when the second plating resist 350 is removed, as illustrated in FIG. 22, the outer layer circuit layer 144 may be formed.

According to the method of FIGS. 13 to 24 as described above, the outer layer build-up layer 140 may be provided with the inner layer build-up layer 120.

According to the method of manufacturing a printed circuit board according to the preferred embodiment of the present invention, as illustrated in FIG. 22, the printed circuit board 100 which includes the inner layer build-up layer 120 including the inner layer via having the tapered section and the outer build-up layer 140 including the outer layer via having the rectangular section may be formed.

The preferred embodiment of the present invention illustrates that the inner layer build-up layer and the outer layer build-up layer are formed on one surface of the base substrate, but is not limited thereto. The inner layer build-up layer and the outer layer build-up layer may be each formed on one surface and both surfaces of the base substrate by a selection of those skilled in the art.

According to the printed circuit board and the method of manufacturing a printed circuit board according to the preferred embodiment of the present invention, the outer layer via is polished before the outer layer circuit layer is formed, thereby removing the dimple of the outer layer via. The occurrence of the dimple on the outer layer circuit layer may be prevented by removing the dimple of the outer layer via. Further, when the inner layer via of the inner layer build-up layer provided with multi-layers is formed, the laser drill machining is used to more reduce handling than when the exposure and developing processes are used, thereby reducing problems which may be caused by the handling. That is, according the printed circuit board and the method of manufacturing a printed circuit board according to the preferred embodiment of the present invention, the laser drill method is applied to the inner layer build-up layer and the exposure and developing processes and the polishing process are applied to the outer layer build-up layer from which the dimple is necessarily removed, thereby simultaneously solving the handling problem and the dimple problem.

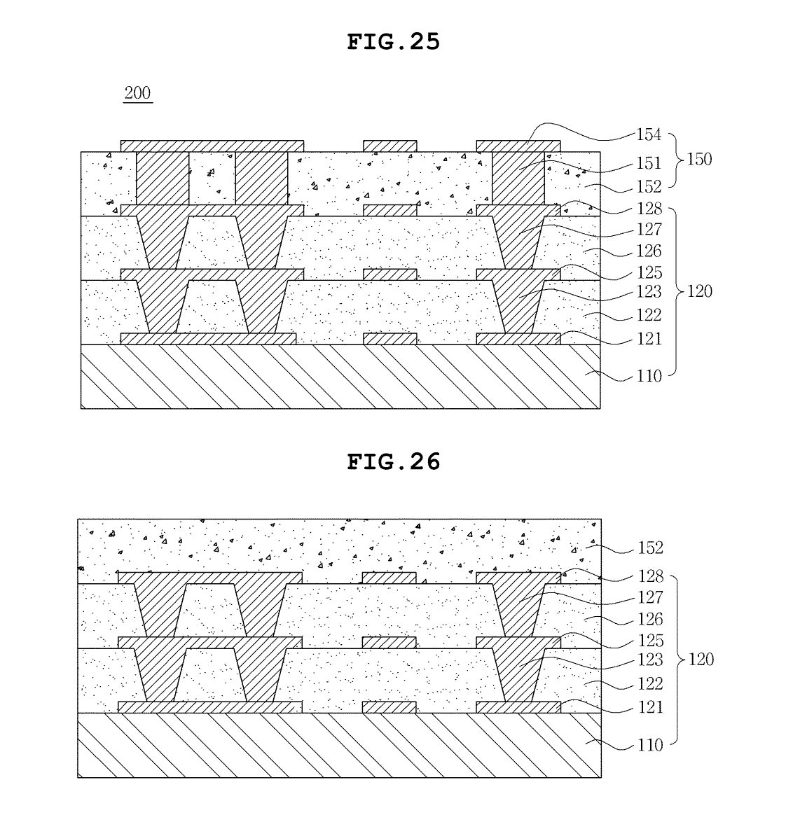

FIG. 25 is an exemplified diagram illustrating a printed circuit board according to another preferred embodiment of the present invention.

Referring to FIG. 25, a printed circuit board 200 may include the base substrate 110, the inner layer build-up layer 120, and the outer layer build-up layer 150.

The base substrate 110 may be generally made of the composite polymer resin used as an interlayer insulating material. For example, the base substrate 110 may be formed using the prepreg, the ajinomoto build up film (ABF), the FR-4, bismaleimide triazine (BT), the copper clad laminate (CCL), and the like.

The preferred embodiment of the present invention illustrates that the base substrate 110 is formed of a single insulating layer, but is not limited thereto. That is, the base substrate 110 may be a build-up layer which is configured to include at least one layer of insulating layer and circuit layer, and the via.

The inner layer build-up layer 120 is formed on the base substrate 110. According to the preferred embodiment of the present invention, the inner layer build-up layer 120 includes the first inner layer circuit layer 121, the first inner layer insulating layer 122, the first inner layer via 123, the second inner layer circuit layer 125, the second inner layer insulating layer 126, the second inner layer via 127, and the third inner layer circuit layer 128.

The first inner layer circuit layer 121 is formed on the base substrate 110.

The first inner layer insulating layer 122 is formed on the base substrate 110 and the first inner layer circuit layer 121.

The first inner layer via 123 is formed in the first inner layer insulating layer 122. The first inner layer via 123 may have one surface bonded to the second inner layer circuit layer 125 and the other surface bonded to the first inner layer circuit layer 121 by penetrating through the first inner layer insulating layer 122. According to the preferred embodiment of the present invention, in order to form the first inner layer via 123, the first inner layer via hole (not illustrated) is formed using the laser drill. In this case, in characteristics of the laser drill, the first inner layer via hole (not illustrated) is formed to have a tapered section. Therefore, the first inner layer via 123 formed by filling the first inner layer via hole (not illustrated) with a conductive material is also formed to have the tapered section. That is, one surface of the first inner layer via 123 may be formed to have a diameter larger than that of the other surface thereof.

The second inner layer circuit layer 125 is formed on the first inner layer insulating layer 122 and the first inner layer via 123. The second inner layer circuit layer 125 is bonded to one surface of the first inner layer via 123.

The second inner layer insulating layer 126 is formed on the first inner layer insulating layer 122 and the first inner layer via 123.

The second inner layer via 127 is formed in the second inner layer insulating layer 126. The second inner layer via 127 may have one surface bonded to the third inner layer circuit layer 128 and the other surface bonded to the second inner layer circuit layer 125 by penetrating through the second inner layer insulating layer 126. According to the preferred embodiment of the present invention, similar to the first inner layer via 123, the second inner layer via 127 may be formed using the laser drill and thus may have the tapered section. That is, one surface of the second inner layer via 127 may be formed to have a diameter larger than that of the other surface thereof.

The third inner layer circuit layer 128 is formed on the second inner layer insulating layer 126 and the second inner layer via 127.

The preferred embodiment of the present invention describes that the inner layer build-up layer 120 includes the two layers of insulating layer and the three layers of circuit layer, but the inner layer build-up layer 120 may be configured to include the various number of layers of insulating layer and circuit layer by a selection of the those skilled in the art.

The outer layer build-up layer 150 is formed on the inner layer build-up layer 120 as the uppermost layer among the build-up layers of the printed circuit board 200. According to the preferred embodiment of the present invention, the outer layer build-up layer 150 includes an outer layer insulating layer 152, an outer layer via 151, and an outer layer circuit layer 154.

The outer layer insulating layer 152 is formed on the second inner layer insulating layer 126 and the third inner layer circuit layer 128. The outer layer insulating layer 152 may be made of a photosensitive insulating material. The photosensitive insulating layer may be any one of a positive type and a negative type.

The outer layer via 151 is formed in the outer layer insulating layer 152. The outer layer via 151 may electrically connect the third inner layer circuit 128 to the outer layer circuit layer 154 by penetrating through the outer layer insulating layer 152. That is, one surface of the outer layer via 151 may be bonded to the outer layer circuit layer 154 and the other surface thereof may be bonded to the third inner layer circuit layer 128. According to the preferred embodiment of the present invention, a section of the outer layer via 151 has a rectangular shape. That is, one surface and the other surface of the outer layer via 151 may be formed to have the same diameter. According to the preferred embodiment of the present invention, in order to form the outer layer via 151, an outer layer via hole (not illustrated) is formed by performing the exposure and developing processes on the outer layer insulating layer 152 made of the photosensitive insulating material. In this case, the outer layer via hole (not illustrated) is formed to have the rectangular section by the exposure and developing processes. Therefore, the outer layer via 151 formed by filling the outer layer via hole (not illustrate) with the conductive material and polishing the upper portion thereof is also formed to have the rectangular section.

The outer layer circuit layer 154 is formed on the outer layer insulating layer 152 and the outer layer via 151. The outer layer circuit layer 154 is bonded to one surface of the outer layer via 151.

According to the preferred embodiment of the present invention, the first inner layer circuit layer 121, the first inner layer via 123, the second inner layer circuit layer 125, the second inner layer via 127, the third inner layer circuit layer 128, the outer layer via 151, and the outer layer circuit layer 154 may be made of the conductive material for the circuit, such as copper, which is used in the circuit board field.

Further, the first inner layer insulating layer 122 and the second inner layer insulating layer 126 are generally made of the composite polymer resin which is used as the interlayer insulating material.

FIGS. 26 to 30 are exemplified diagrams illustrating a method of manufacturing a printed circuit board according to another preferred embodiment of the present invention.

The inner layer build-up layer 120 of the printed circuit board 200 according to another embodiment of the present invention may be formed by the same method as FIGS. 2 to 12. Therefore, the method of forming an inner layer build-up layer 120 is described with reference to FIGS. 2 to 12 and the description thereof will be omitted.

Referring to FIG. 26, the outer layer insulating layer 152 is formed in the inner layer build-up layer 120.

According to the preferred embodiment of the present invention, the outer layer insulating layer 152 may be made of the photosensitive insulating material. For example, the outer layer insulting layer 152 may be formed of a dry film.

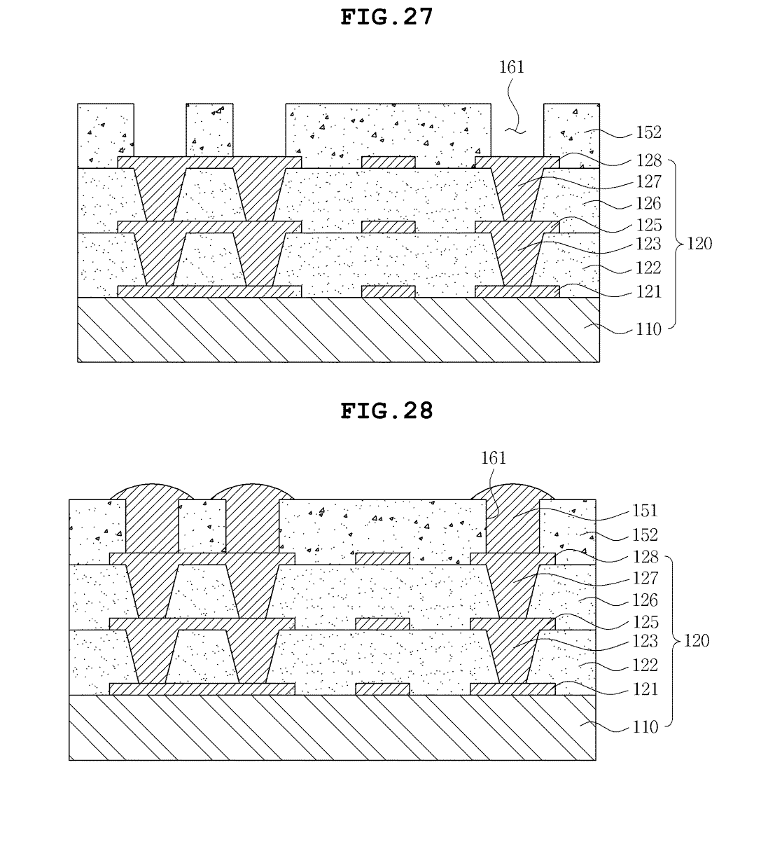

Referring to FIG. 27, the outer layer insulating layer 152 is provided with an outer layer via hole 161.

The outer layer via hole 161 may be formed by performing the exposure and developing processes on the outer layer insulating layer 152. Therefore, the outer layer via hole 161 may be formed to have the rectangular section in which the upper and lower portions of the outer layer via hole 161 have the same diameter. The outer layer via (not illustrated) is formed on the third inner layer circuit layer 128, such that the outer layer via hole 161 may be formed on the third inner layer circuit layer 128.

Referring to FIG. 28, the outer layer via 151 is formed.

The outer layer via 151 may be formed by plating the outer layer via hole 161 of the outer layer insulating layer 152. Herein, the outer layer via 151 may be made of the conductive material for the circuit, such as copper. The method of forming an outer layer via 151 is not limited to the plating, but may be any one of the methods of forming a circuit or a via in the circuit board field.

The so formed outer layer via 151 may be bonded to the third inner layer circuit layer 128.

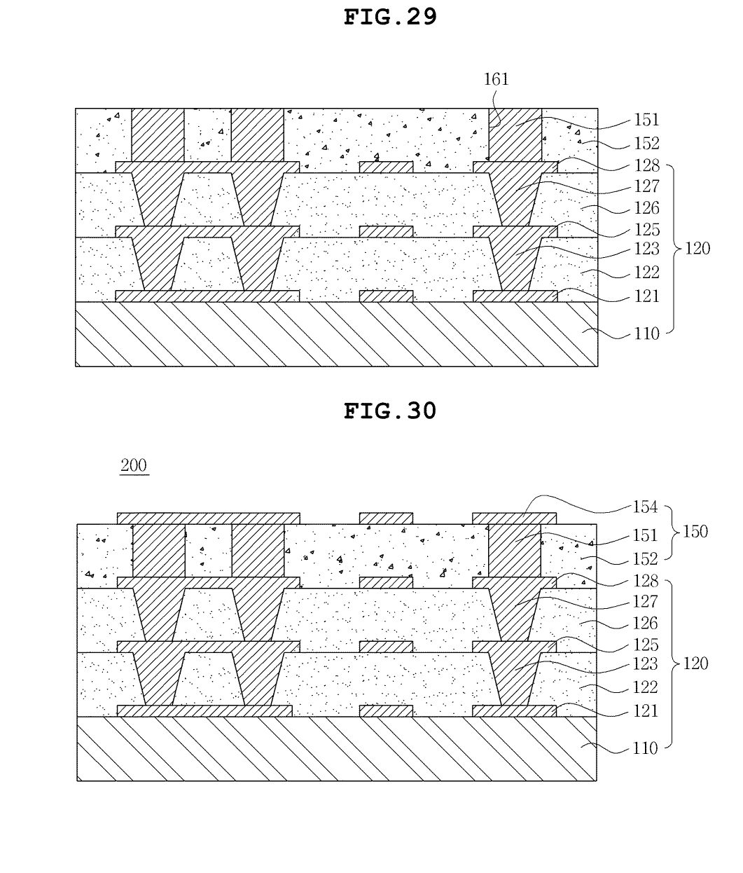

Referring to FIG. 29, the outer layer via 151 is polished.

The outer layer via 151 may be overcoated up to an upper portion of the outer layer insulating layer 152 as illustrated in FIG. 28. Further, although not illustrated, the outer layer via 151 may not be sufficiently formed up to an upper surface of the outer layer via hole 161. Therefore, the outer layer via 151 or the upper portion of the outer layer via 151 and the outer layer insulating layer 152 may be planarized by being polished.

As described above, a dimple formed on the upper portion of the outer layer via 151 may be removed by polishing the outer layer via 151. Further, the occurrence of the dimple on the outer layer circuit layer (not illustrated) formed on the upper portion of the outer layer via 151 may be prevented by removing the dimple on the outer layer via 151.

Further, when the outer layer via 151 is formed in plural, all the outer layer vias may be formed to have a uniform height.

Referring to FIG. 30, the outer layer insulating layer 152 and the outer layer via 151 are provided with the outer layer circuit layer 154.

The outer layer circuit layer 154 may be formed by one of the methods of forming the outer layer circuit layer described with reference to FIGS. 20 to 24.

The outer layer build-up layer 150 may be formed by forming the outer layer insulating layer 152, the outer layer via 151, and the outer layer circuit layer 154 as described above.

According to the method of manufacturing a printed circuit board according to another preferred embodiment of the present invention, as illustrated in FIG. 30, the printed circuit board 200 which includes the inner layer build-up layer 120 including the inner layer via having the tapered section and the outer build-up layer 150 including the outer layer via having the rectangular section may be formed. Further, the outer layer insulating layer 152 of the outer layer build-up layer 150 may be made of the photosensitive insulating material.

According to the printed circuit board and the method of manufacturing a printed circuit board according to the preferred embodiment of the present invention, the laser drill method is applied to the inner layer build-up layer and the exposure and developing processes and the polishing process are applied to the outer layer build-up layer from which the dimple is necessarily removed, thereby simultaneously solving the handling problem and the dimple problem. Further, the number of processes of forming the outer layer build-up layer by using the outer layer insulating layer made of the photosensitive insulating material is reduced, thereby reducing the cost and time.

The preferred embodiment of the present invention describes, by way of example, the tenting method and the SAP method as the method of forming an inner layer circuit layer and an outer layer circuit layer, but is not limited thereto. The inner layer circuit layer and the outer layer circuit layer may also be formed by any known method in the circuit board field.

According to the printed circuit board and the method of manufacturing a printed circuit board according to the preferred embodiments of the present invention, when the outer layer via is formed, the dimple may be removed by using the exposure and developing processes and the polishing process.

According to the printed circuit board and the method of manufacturing a printed circuit board according to the preferred embodiments of the present invention, when the inner layer via of the inner layer build-up layer having the multi-layer structure is formed, the handling problem may be reduced by using the laser drill.

According to the printed circuit board and the method of manufacturing a printed circuit board according to the preferred embodiments of the present invention, the reduction in the handling problem and the removal of the dimple may be solved simultaneously.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a base substrate;
an inner layer build-up layer formed on the base substrate and including a first inner layer circuit layer, a second inner layer circuit layer, an inner layer insulating layer, and an inner layer via having a tapered section; and
an outer layer build-up layer formed on the inner layer build-up layer and including an outer layer circuit layer, an outer layer insulating layer, and an outer layer via having a rectangular section.

2. The printed circuit board as set forth in claim 1, wherein the inner layer build-up layer includes at least one of the first inner layer circuit layer, the second inner layer circuit layer, the inner layer insulating layer, and the inner layer via.

3. The printed circuit board as set forth in claim 1, wherein the inner layer build-up layer includes:
the first inner layer circuit layer formed on the base substrate;
the inner layer insulating layer formed on the base substrate and the first inner layer circuit layer;
the inner layer via formed on the first inner layer circuit layer and formed to penetrate through the inner layer insulating layer; and
the second inner layer circuit layer formed on the inner layer insulating layer and the inner layer via.

4. The printed circuit board as set forth in claim 1, wherein the outer layer build-up layer includes:
the outer layer insulating layer formed on the inner layer build-up layer;
the outer layer via formed on the inner layer build-up layer and formed to penetrate through the outer layer insulating layer; and
the outer layer circuit layer formed on the outer layer insulating layer and the outer layer via.

5. The printed circuit board as set forth in claim 1, wherein the outer layer insulating layer is made of a photosensitive insulating material.

6. The printed circuit board as set forth in claim 1, wherein the inner layer build-up layer and the outer layer build-up layer are formed on both surfaces of the base substrate.

7. A method of manufacturing a printed circuit board, comprising:
preparing a base substrate;
forming an inner layer build-up layer including a first inner layer circuit layer, a second inner layer circuit layer, an inner layer insulating layer, and an inner layer via having a tapered section on the base substrate; and
forming an outer layer build-up layer including an outer layer circuit layer, an outer layer insulating layer, and an outer layer via having a rectangular section on the inner layer build-up layer.

8. The method as set forth in claim 7, wherein the inner layer build-up layer includes at least one of the first inner layer circuit layer, the second inner layer circuit layer, the inner layer insulating layer, and the inner layer via.

9. The method as set forth in claim 7, wherein the forming of the inner layer build-up layer includes:
forming the first inner layer circuit layer on the base substrate;
forming the inner layer insulating layer on the first inner layer circuit layer; and
forming the inner layer via and the second inner layer circuit layer on the inner layer insulating layer.

10. The method as set forth in claim 9, wherein the forming of the inner layer via and the second inner layer circuit layer includes:
forming an inner layer via hole having a tapered section in the inner layer insulating layer by using a laser drill;
forming an inner layer conductive layer and the inner layer via by forming a conductive material in the inner layer insulating layer and the inner layer via hole;
forming a first etching resist passivating a region, in which the second inner layer circuit layer is formed, on the inner layer conductive layer;
forming the second inner layer circuit layer by etching the inner layer conductive layer exposed by the first etching resist; and
removing the first etching resist.

11. The method as set forth in claim 9, wherein the forming of the inner layer via and the second inner layer circuit layer includes:
forming the inner layer via hole having the tapered section in the inner layer insulating layer by using the laser drill;
forming a first plating resist exposing a region, in which the inner layer via hole and the second inner layer circuit layer are formed, on the inner layer insulating layer;
forming the inner layer via and the second inner layer circuit layer by forming the inner layer via hole and the inner layer insulating layer exposed by the first plating resist; and
removing the first plating resist.

12. The method as set forth in claim 7, wherein the forming of the outer layer build-up layer includes:
forming the outer layer via on the inner layer build-up layer;
forming the outer layer insulating layer formed on the inner layer build-up layer and having the outer layer via embedded therein; and
forming the outer layer circuit layer on the outer layer insulating layer and the outer layer via.

13. The method as set forth in claim 12, wherein the forming of the outer layer via includes:
forming a photosensitive resist on the inner layer build-up layer;
forming an opening having a rectangular section and exposing a region in which the outer layer via is formed, by exposing and developing the photosensitive resist;
forming the outer layer via by forming an insulating material in the opening;
polishing and planarizing an upper portion of the outer layer via; and
removing the photosensitive resist.

14. The method as set forth in claim 12, further comprising: after the forming of the outer layer insulating layer, polishing and planarizing the outer layer insulating layer and the outer layer via.

15. The method as set forth in claim 12, wherein the forming of the outer layer circuit layer includes:
forming an outer layer conductive layer by forming an insulating material in the outer layer insulating layer and the outer layer via;
forming a second etching resist on the outer layer conductive layer to passivate a region in which the outer layer circuit layer is formed;
forming the outer layer circuit layer by etching the outer layer conductive layer exposed by the second etching resist; and
removing the second etching resist.

16. The method as set forth in claim 12, wherein the forming of the outer layer circuit layer includes:
forming a second plating resist which exposes the outer layer insulating layer and the region in which the outer layer circuit layer is formed in the outer layer via;
forming the outer layer circuit layer by forming a conductive material in the outer layer insulating layer and the outer layer via exposed by the second plating resist; and
removing the second plating resist.

17. The method as set forth in claim 7, wherein the forming of the outer layer build-up layer includes:
forming the outer layer insulating layer made of a photosensitive insulating material on the inner layer build-up layer;
forming the outer layer via formed to penetrate through the outer layer insulating layer; and
forming the outer layer circuit layer on the outer layer insulating layer and the outer layer via.

18. The method as set forth in claim 17, wherein the forming of the outer layer via includes:
forming an outer layer via hole having a rectangular section and exposing a region in which the outer layer via is formed, by exposing and developing the outer layer insulating layer;
forming the outer layer via by forming a conductive material in the outer layer via hole; and
polishing and planarizing upper portions of the outer layer insulating layer and the outer layer via.

19. The method as set forth in claim 17, wherein the forming of the outer layer circuit layer includes:
forming an outer layer conductive layer by forming an insulating material in the outer layer insulating layer and the outer layer via;
forming a second etching resist on the outer layer conductive layer to passivate the region in which the outer layer circuit layer is formed;
forming the outer layer circuit layer by etching the outer layer conductive layer exposed by the second etching resist; and
removing the second etching resist.

20. The method as set forth in claim 17, wherein the forming of the outer layer circuit layer includes:
forming a second plating resist which exposes the outer layer insulating layer and the region in which the outer layer circuit layer is formed in the outer layer via;
forming the outer layer circuit layer by forming a conductive material in the outer layer insulating layer and the outer layer via exposed by the second plating resist; and
removing the second plating resist.

21. The method as set forth in claim 7, wherein the inner layer build-up layer and the outer layer build-up layer are formed on both surfaces of the base substrate.
